(19) United States
(12) Patent Application Publication
(10) Pub. No.: US 2014/0227925 A1
(43) Pub. Date: Aug. 14, 2014

(54) NOVEL METAL POLYOXIDE, AND FUNCTIONAL FIBER OR TEXTILE PREPARED USING METAL POLYOXIDE

(71) Applicants: Seung Won Kook, Busan (KR); Alexandru Botar, Busan (KR)

(72) Inventors: Seung Won Kook, Busan (KR); Alexandru Botar, Busan (KR)

(21) Appl. No.: 14/240,630

(22) PCT Filed: Aug. 24, 2012
(86) PCT No.: PCT/KR2012/006781

§ 371 Date: Feb. 24, 2014

(30) Foreign Application Priority Data
Aug. 25, 2011 (KR) 10-2011-0085181
Mar. 8, 2012 (KR) 10-2012-0024050

(51) Int. Cl. C30B 7/14; D02G 3/44; D06M 11/36; D02G 3/36; C01G 45/02; C01G 51/04

(52) U.S. Cl. CPC C30B 7/14; C01G 45/02; C01G 51/04; D06M 11/36; D02G 3/36; D02G 3/449
USPC 442/123; 423/599; 423/594.5; 117/68; 428/389; 428/221

(57) ABSTRACT

A novel metal polyoxide is a compound in which a plurality of oxygen elements are coupled to a transition metal element, and shows surface electrical resistance in addition to antibacterial and deodorizing activities. More specifically, the metal polyoxide contains manganese (III) molybdate and cobalt (III) molybdate having a novel structure. A preparation method thereof and a preparation method of a functional fiber or textile prepared using the same are provided.

### TECHNICAL FIELD

The present invention relates to a novel metal polyoxides, and a functional fiber or textile prepared using the metal polyoxides.

### BACKGROUND ART

Metal polyoxides (henceforth referred to as MP) is a polyatomic ion that is mainly negative ion and is comprised of three or more clusters of transition metal oxygen anion with big three-dimensional structure as the elements are connected by oxygen atoms.

Metal atoms that construct metal polyoxides are mostly transition metals with five or six groups with a high state of oxidation wherein the electron configuration is either d⁰ or d¹. Specific examples of metal atoms are vanadium (V), niobium (V), tantalum (V), molybdenum (VI), and tungsten (VI).

MP can be largely classified into two types, i.e., isopoly anion comprised of only transition metal and oxide anion, and hetero poly anion comprising heteroatom with p or d orbital in addition to the transition metal and oxide anion. Representative example of the hetero poly anion is phosphotungstate anion, wherein framework structure of transition metal oxygen anion is surrounded by heteroatom such as silicon and phosphorus and shares neighboring oxygen atom.

The very first MP compound, ammonium phosphomolybdate ([PMo₁₂O₄₀]³⁻) was discovered in 1826. In 1934, it was discovered that ammonium phosphomolybdate has the same structure with phosphotungstate anion and was referred to as the Keggin Structure thenceforth. pho After this discovery, MP with high symmetry as well as organic and inorganic hybrid substances had been developed wherein their magnetic, optical, medical characteristics and related applied researches had been made known.

MP has different basic framework according to the type of compound. The most well-known framework is Keggin heteropoly anion ([Xⁿ⁺M₁₂O₄₀]⁽⁸⁻ⁿ⁾⁻) with characteristics such as having well established identification of the compounds optically, being easily synthesized and having very stable structure. In the case of this Keggin structure, compound such as molybdate and tungstate are commonplace wherein molybdate and tungstate may be substituted with other transition metal, organic metal or organic group. Lindqvist structure has isopoly anion structure wherein decavanadate, paratungstate and molybdenum 36-polymolybdate have heteropolyanion structure. Keggin and Dawson structure has tetrahedron coordinate structure with phosphorus or silicon atom at the center wherein Anderson structure has octahedron coordinate structure with aluminum atom at the center. There are other known basic structures aside from the ones that had been mentioned.

The metal atom known as ‘addenda atom’ usually refers to molybdenum, tungsten, vanadium and others. When two or more metal atoms are included in the framework structure, it is referred to as ‘compound addenda cluster’. Ligand, which is usually an oxide anion, has cross-linking framework structure wherein the oxide anion can be substituted by bromide dioxide, nitrosyl or an alkoxy. Typical formation of framework structure has polyhedron unit with metal in the center with 4 to 7 coordination. These units share the edge or vertex of the entire framework structure.

Hetero atom is located at central part of the anion in the MP wherein various coordination numbers such as 4 coordination (it can be usually found in Keggin, Dawson, and Lindqvist structure and in tetrahedron, PO₄, SiO₄, AsO₄ and more) 6 coordination (Anderson structure, octahedron, A1(OH)₆, TeO₆), 8 coordination (tetragon anti-prism, [(CeO₈)W₁₀O₂₈]⁸⁻), and 12 coordination (icosahedrons, [(UO₁₂)Mo₁₂O₃₀]⁸⁻) exists. Most interesting thing about the MP structure is that it usually has structural isomer. Keggin structure has five isomer structures and four M₃O₁₃ units have been rotated by 60 degrees.

The huge size and structure of MP that had been explained previously shows various characteristics such as solubility of water and organic solvent, stability in terms of heat, low toxicity, ability as carrier of electricity and oxygen, strong absorption in the ultraviolet visible light (<400 nm), maintaining the structure when returned as well as re-oxidation of returned MP through various oxidizer such as oxygen, proton, metal anion among others.

MP with different types of structure had been synthesized until the present and its structure had been made known wherein various characteristics of MP as it had been mentioned shows that how it can be widely applied to interesting areas. Characteristics of MP are very dependent on the types of metal and its structure. Therefore, new development of MP with various metal atoms can boost the characteristics of pre-existing MP. It is a very significant area of interest in the sense that there are possibilities of discovering entirely new characteristics.

Moreover, there are more consumers that demand for more comfort as the quality of life has been increased. In order to meet this need, functional textile with antibacterial effects, far-infrared ray and anion eliminates various microorganisms that live as parasites in the fiber and thereby causing various diseases and bad odor which guarantees good quality of life. Currently, this functional textile is being used for various purposes and demand for it is significantly on the rise.

The method used in prior art to add antibacterial function is to coat the surface with silver (Ag) or silver salt (Ag salt) (U.S. Pat. No. 5,395,651); method of coating the surface with biguanide (U.S. Pat. No. 4,999,210, No. 5.013,306 and No. 5,707,366); method of coating the surface with alumino-silicate or zeolite (U.S. Pat. No. 5,556,699); and the method of coating the surface with polyisocyanate, organic functional silane and composite which is a reaction product that includes silane copolymer (U.S. Pat. No. 6,596,401) among others.

Prior art mainly uses the method of coating or sticking inorganic antibacterial substance to the fiber, textile or surface of the equipment. However, such a physical adsorption method has short-lived effect and can easily be washed away during cleaning. Especially, the inorganic ceramic antibacterial has its own strong color and presents the problem of not being able to dye it with various colors.

Therefore, there is a need for research and development for producing new type of functional fiber or textile that can solve the problem regarding functional decline and changes in inherent characteristics due to physical absorption process.

The inventors of present invention have confirmed that if MP is added to the fiber or textile after cationization thereof, owing to strong ionic bonding, functionality of the fiber or textile is not decreased until the fiber or textile is worn out, inherent characteristics of fiber or the textile do not change, excellent antibacterial and deodorizing effects are shown and also surface resistance is increased, and the present invention has been thus completed.

### SUMMARY OF INVENTION

### Technical Problem

Accordingly, the present invention has been made in view of the above mentioned problems occurring in the prior art, and it is an object of the present invention is to provide metal polyoxides with a new structure.

Another object of the present invention is to provide producing method of novel metal polyoxides.

Another object of the present invention is to provide functional fiber or textile which includes metal polyoxides coupled with strong ion fusion.

Another object of the present invention is to provide producing method of functional fiber or textile by chemical combining metal polyoxides to the fiber or textile.

Yet another object of the present invention is to provide various produced products made from functional fiber or textile with metal polyoxides.

### Solution to Problem

In order to solve the above problem, present invention provides metal polyoxides with new structure as represented by chemical formula 1 or chemical formula 2 as seen below.

H₇MnMo₉O₃₂.xH₂O [Chemical Formula 1]

In chemical formula 1, x is the number of water wherein it is a real number from 10 to 20.

H₉CoMo₆O₂₄.yH₂O [Chemical Formula 2]

In chemical formula 2, y is the number of water wherein it is a real number of 5 to 15.

In order to solve the above problem, present invention provides a method for producing metal polyoxides represented by said chemical formula 1 or chemical formula 2 wherein the method comprises stage (i) wherein hydrated molybdenum oxide is added to aqueous solution of hydrogen peroxide to produce aqueous solution of molybdenum; stage (ii) wherein metal compound solution is produced by adding hydrated manganese or hydrated cobalt to the aqueous solution of molybdenum to be heated afterwards; stage (iii) wherein the metal compound solution is concentrated; and stage (iv) wherein the concentrated solution is crystallized to retrieve crystal of metal polyoxides;

In order to solve the above problem, present invention provides a producing method of functional fiber or textile with metal polyoxide added thereto wherein the method comprises:; stage (a) wherein fiber or textile is cationized; and stage (b) wherein the cationized fiber or textile is immersed into aqueous solution of metal polyoxides which includes one or more transition metals selected from tungsten, molybdenum, manganese, cobalt, vanadium and chrome to add the metal polyoxides.

In order to solve the above problem, present invention provides a producing method of functional fiber or textile wherein the method comprises stage (a) wherein fiber or textile is cationized; stage (b) wherein the cationized fiber or textile is immersed into aqueous solution of metal polyoxides which includes one or more transition metals selected from tungsten, molybdenum, manganese, cobalt, vanadium and chrome to add the metal polyoxides; and stage (c) wherein the functional fiber or textile with metal polyoxides added thereto is immersed into aqueous solution which includes one or two or more functional metal salt selected from the group of silver, copper, tin, zinc and palladium to add the functional metal.

In order to solve the above problem, the present invention provides functional fiber or textile with metal polyoxide added thereto wherein metal polyoxide comprising one or more transition metal selected from tungsten, molybdenum, manganese, cobalt, vanadium and chrome is included in the cationized fiber or textile through chemical bonding.

In order to solve the above problem, present invention provides products that are produced by making use of functional fiber or textile with metal polyoxides.

### Advantageous Effects of Invention

Metal polyoxides according to the present invention has excellent antibacterial and deodorizing effects as well as surface electrical resistance and when it is added to fiber or textile, it provides functional fiber or textile with excellent antibacterial, deodorizing, and electromagnetic shielding effect. Products made with functional fiber or textile can be widely used as clothing made with natural textile, fiber blend or textile with high value wherein it can be used to make long underclothes, insole, wallpaper, air filter or clothes with antibacterial, deodorizing, and electromagnetic shielding effects.

Moreover, as metal polyoxides was added to cationized fabric or textile through strong ionic bonding process and not through physical absorption, it can continuously maintain antibacterial and deodorizing effects for a long term.

This is the first invention that coupled metal polyoxides to natural fiber or textile and as functional fiber or textile provides excellent antibacterial and deodorizing effects, it is proven to have excellent antibacterial and deodorizing effects which leads to efficient elimination of house ticks and other pests. Moreover, effects of metal polyoxides used in present invention are boosted further by silver, copper, tin, zinc, palladium and other functional metal.

Moreover, functionality of present invention can be carried out with ease and the by-products produced during reaction are non-toxic therefore environmental friendly. In case of cationization, process will be a very economical, single step process in the room temperature instead of uneconomical pre-existing two-step thermal process that disintegrates the cellulose.

This single step process also has the advantage as it does not involve pre-treatment that processes the fiber or textile with strong sodium hydroxide for methoxylation.

### BRIEF DESCRIPTION OF DRAWINGS

FIG. 1 is a picture illustrating the crystal of H₇MnMo₉O₃₂.15H₂O and H₉CoMo₆O₂₄.10H₂O

FIG. 2 is a graph illustrating the infrared light spectrum for H₇MnMo₉O₃₂.15H₂O

FIG. 3 is a graph illustrating the infrared light spectrum for H₉CoMo₆O₂₄.10H₂O

FIG. 4 is a graph illustrating the ultraviolet visible light spectrum of H₇MnMo₉O₃₂.15H₂O

FIG. 5 is a graph illustrating the ultraviolet visible light spectrum of H₉CoMo₆O₂₄.10H₂O

FIG. 6 is a picture illustrating the structure of unit cell and packing produced by single crystal x-ray crystallography of H₇MnMo₉O₃₂.15H₂O

FIG. 7 illustrates the structure of unit cell and packing produced by single crystal x-ray crystallography of H₉CoMo₆O₂₄.10H₂O

FIG. 8 shows pictures of cotton textile obtained from 1) cotton textile before the treatment, 2) stage wherein cationization process takes place, 3) stage wherein potassium phosphate molybdenum vanadate is added, 4) stage wherein copper salt is added, and 5) reduction stage, respectively, of Example 1.

FIG. 9 shows pictures of cotton textile obtained from 1) stage wherein silver salt is coupled with cotton textile after potassium phosphorus molybdenum vanadate had been added, and 2) reduction stage, respectively, of Example 2.

FIG. 10 shows pictures of cellulose textile obtained from 1) cellulose textile before the treatment process, 2) cationization stage, 3) stage wherein potassium phosphorus molybdenum vanadate is added, 4) stage wherein copper salt is added, and 5) reduction stage, respectively, Example 3.

FIG. 11 shows pictures of cellulose textile obtained from 1) stage where cationized fiber is fused with palladium after ammonium molybdate is added, and 2) reduction stage, respectively, Example 4.

FIG. 12 shows pictures of cotton textile obtained from 1) stage where silver salt is coupled with cellulose textile after ammonium molybdate is added; and 4) reduction stage, respectively, Example 5.

FIG. 13 shows pictures of cotton textile obtained from 1) stage where potassium phosphorus molybdenum vanadate is added to cationized textile, 2) stage wherein copper salt is coupled; and 3) reduction stage, respectively, Example 6.

FIG. 14 shows pictures of cellulose textile obtained from 1) stage where silver salt is coupled with cellulose textile after adding potassium phosphorus molybdenum vanadate, 2) reduction stage, respectively, Example 7.

FIG. 15 shows pictures of cellulose textile obtained from 1) stage where silicon molybdate is added to the cationized textile, and 2) stage wherein copper salt is coupled, and 3) reduction stage, respectively, Example 8.

FIG. 16 shows pictures of cotton textile obtained from 1) cotton textile before the treatment, 2) cationization stage, 3) stage where manganese (III) molybdate is added, 4) stage wherein copper salt is coupled, and 5) reduction stage, respectively, Example 9.

FIG. 17 shows pictures of cotton textile obtained from 1) cotton textile before the treatment, 2) cationization stage, 3) stage wherein cobalt (III) molybdate is added, 4) silver salt is coupled, and 5) reduction stage, respectively, Example 10.

FIG. 18 is a picture illustrating scanning electronic microscope image of functional textile as produced by Example 10.

### BEST MODE

Present invention relates to functional fiber or textile with functions such as antibacterial, deodorization and electromagnetic shielding effect made possible through the process wherein metal polyoxides was added to the fiber or textile.

The metal polyoxide used by the present invention is metal polyoxide comprising one or more transition metal selected from tungsten, molybdenum, manganese, cobalt, vanadium and chrome. Types of transition atoms that construct metal polyoxides have d or f orbital electron thus having negative charge wherein this enables the metal polyoxides to have strong ionized bonding. Specifically, metal polyoxides used by the present invention are potassium molybdenum vanadate, potassium tungsten vanadate, phosphorus molybdovanadate, sodium phosphorus molybdovanadate, silicon molybdate, phosphorous molybdate, phosphorous tungstenite, ammonium molybdate, ammonium polyoxomolybdate and manganese molybdate as represented by chemical formula 1 as well as cobalt molybdate as represented by chemical formula 2 wherein one or two groups can be used from these two groups. It is recommended that two or more metal polyoxides would be used as mixed as it is provides compound effect.

H₇MnMo₉O₃₂.xH₂O [Chemical Formula 1]

In chemical formula 1, x is the number of water wherein it is a real number from 10 to 20.

H₉CoMo₆O₂₄.yH₂O [Chemical Formula 2]

In chemical formula 2, y is the number of water wherein it is a real number of 5 to 15.

Moreover, pre-existing characteristics of functional fiber or textile such as antibacterial, deodorization and electromagnetic shielding effects are maximized by coupling one or two metal salts from the group of silver, copper, tin, zinc and palladium to metal polyoxides.

Moreover, in the case of metal polyoxides included in the functional fiber or textile, manganese (III) molybdate represented by chemical formula 1 and cobalt (III) molybdate represented by chemical formula 2 are both novel metal polyoxides. These novel metal polyoxides that are represented by chemical formula 1 or two have new structure that haven't been made known before with excellent antibacterial, deodorization and electromagnetic shielding effects and especially against house ticks that are known to cause various skin diseases such as atopy and others.

Therefore, present invention includes metal polyoxides as well as the producing method of the metal polyoxides as represented by chemical formula 1 or 2 within its scope of right.

Producing method of metal polyoxides as represented by said chemical formula 1 or 2 according to the present invention a method for producing metal polyoxides represented by said chemical formula 1 or chemical formula 2 comprises stage (i) wherein hydrated molybdenum oxide is added to aqueous solution of hydrogen peroxide to produce aqueous solution of molybdenum; stage (ii) wherein metal compound solution is produced by adding hydrated manganese or hydrated cobalt to the aqueous solution of molybdenum to be heated afterwards; stage (iii) wherein the metal compound solution is concentrated; and stage (iv) wherein the concentrated solution is crystallized to retrieve crystal of metal polyoxides;

There are no restrictions regarding the use of as hydrated molybdenum oxide, manganese hydrate or cobalt hydrate as they have been used in prior art in regards to the present invention. Monohydrate (MoO₃.H₂O) can be used as hydrated molybdenum oxide and manganese chloride tetrahydrate (MnCl₂.4H₂O) can be used as manganese hydrate. Sulfurized manganese hydrate (MnSO₄.H₂O) and manganese acetate dihydrate (Mn(CH₃COO)₃.2H₂O) can be used as well. Cobalt chloride hexahydrate (CoCl₂.6H₂O), sulfurized heptahydrate (CoSO₄.7H₂O) or cobalt acetate tetrahydrate (Co(CH₃COO)₂.4H₂O) can be used as cobalt hydrate. Compounds that are mentioned above are examples of the components that can be obtained easily. Other metal polyoxides that include molybdenum, manganese or cobalt can be applied to the present invention.

Hydrogen peroxide solution used in stage (i) as mentioned above is prepared by diluting the 30% hydrogen peroxide in distilled water and it is recommended to be used after making it into a diluted solution of 10-15%.

Manganese hydrate or cobalt hydrate as used in stage (ii) is recommended to be at a 1.0 to 1.1 range of weight ratio as compared to the weight of hydrated molybdenum oxide. Moreover, it is recommended that heating process in stage (ii) would be with the heat of 60 to 80 degree Celsius for the duration of 30 to 60 minutes. When heating temperature is less than 60 degree Celsius, problem could occur wherein reaction may not be enough and when heating temperature is over 80 degree Celsius, concentration process may take place which could also cause a problem in terms of reaction.

It is recommended that concentration process in stage (iii) should proceed by heating it from 80 to 100 degree Celsius for the duration of 30 to 60 minutes. When heating temperature is less than 80 degree Celsius, there is a chance that concentration process might not happen and if heating temperature is over 100 degree Celsius, concentration process may take place too rapidly which could also cause a problem as this affects purity.

In regards to crystallization as mentioned above in stage (iv), it is a crystallization method as used in prior art wherein concentrated solution prepared by stage (iv) is left in room temperature wherein the crystals are filtered and collected. The present invention does not set particular limitation on the crystallization method.

Moreover, present invention includes producing method of functional fiber or textile with metal polyoxides within its scope of right.

Producing method of functional fiber or textile according to the present invention comprises stage (a) wherein fiber or textile is cationized; and stage (b) wherein the cationized fiber or textile is immersed into aqueous solution of metal polyoxides which includes one or more transition metals selected from tungsten, molybdenum, manganese, cobalt, vanadium and chrome to add the metal polyoxides.

Moreover, producing method regarding functional fiber or textile after stage (b) according to the present invention comprises, after stage (b), stage (c) wherein functional fiber or textile with metal polyoxides is immersed into solution which includes one or more functional metal salt from the group of silver, copper, tin, zinc and palladium. This maximizes the pre-existing characteristics of functional fiber or textile such as antibacterial, deodorization and electromagnetic shielding effects.

Fiber that may be used in present invention includes natural fiber, artificial fiber and fiber blend; there are no particular restrictions in terms of fiber.

Examples of natural fiber are ramie, paper mulberry, cotton, silk, wool or cashmere and examples of artificial fiber are cellulose and amide among others. Moreover, it is recommended that fiber or textile in stage (a) be ionized before it is cationized through previous treatment methods.

Cationization is an important chemical method necessary for producing functional fiber or textile as the final product wherein metal polyoxides with multiple negative charges that serves as core functionality is added through fiber cationization which occurs by safe chemical compound and very stable static electricity with ionized bonding.

Cationization is an important chemical process required to manufacture functional fiber or textile wherein metal polyoxides with multiple negative charges that serves as core functionality is added through fiber cationization which occurs by safe chemical compound and very stable static electricity with ionized bonding is added to fiber or textile in the present invention.

Metal polyoxides with strong oxidization is added to fiber or textile for development of functional fiber or textile with excellent antibacterial and deodorizing effects. Moreover, it has excellent eliminating capability for removing house ticks and also has exceptional quality in terms of mechanical stability such as resistance against distortion, shrinking and durability to resist against pressure among others.

More specific explanation regarding producing method of functional fiber or textile according to the present invention is as follows.

Cationization is a necessary process so that functionality can be provided to fiber or textile. Various reagents can be used for cationization process of fiber or textile. For example, cationized reagents such as 3-chloro-2-hydroxypropyl trimethyl chloride ammonium (CHTAC), 2-chloroethyldiethylamine hydrogen chloride (DEAEC1.HCl) can be used as well.

Moreover, cationization process of fiber or textile by using cationized reagents such as elevating temperature method or exhaustion method or a cold pad-batch method and various other methods are used in prior art.

It is recommended that fiber or textile would go through the Anionic process before the cationization process. Anionic process can be carried out by various methods as it had been mentioned. After this, metal polyoxides is added to cationized fiber or textile to manufacture functional fiber or textile with strong ionized bonding.

Moreover, present invention fuses one or more functional metal salt from the group of silver, copper, tin, zinc and palladium to metal polyoxide which is added to fiber or textile to maximize antibacterial, deodorization and electromagnetic shielding effects. When multiple ions are added to cationized fiber or textile, multiple oxygen ions provides antibacterial, deodorization and electromagnetic shielding effect and when various functional metals are combined additionally, functional fiber or textile with maximized effect is created.

Present invention provides functional fiber or textile with metal polyoxides to cationized fiber or textile. Functional fiber or textile has stably bonded with metal polyoxide through ionized bonding wherein excellent antibacterial and deodorization effects as provided by strong oxidation. Moreover, it is possible to manufacture paper or clothes through the above mentioned fiber or textile as well as medical supplies such as bandage and wound dressings. More specifically, it can be used for various purposes such as clothing made with natural textile, fiber blend or textile with high value or long underclothes, insole, wallpaper, air filter or clothes with antibacterial, deodorizing, and electromagnetic shielding effects.

### Description of Embodiments

While the present invention has been described with reference to the particular illustrative embodiments, it is not to be restricted by the embodiments but only by the appended claims.

The following illustrates the preparation methods regarding inventive metal polyoxides representative by the following chemical formula 1 or 2 which is the characteristics of the present invention. However, it should be noted that theses descriptions do not limit nor restrict the present invention.

### PRODUCTION EXAMPLE

### Producing of Metal Polyoxides

### Production Example 1

### Synthesizing of Manganese (III) Molybdate (H₇MnMo₉O₃₂.15H₂O)

80 mL of distilled water and 30 percent of 20 mL hydrogen peroxide are placed in the beaker to be stirred wherein four grams of monohydrate molybdenum oxide (MoO₃.H₂O) is added in. During this stage, color of the solution was greenish yellow. Four grams of manganese chloride tetrahydrate (MnCl₂.4H₂O) was placed into the solution and was heated for 30 minutes at 70 degree Celsius. After this, color of the solution changed to orange then heated again for 30 minutes at 90 degree Celsius wherein color of the solution changed to darker shade of orange. Concentrated solution was filtered with filter paper while still hot wherein it was placed in room temperature all night for crystallization after small amount of yellowish deposit had been removed. 2.5 grams of solid, orange colored crystal with 60 percent yield rate was obtained.

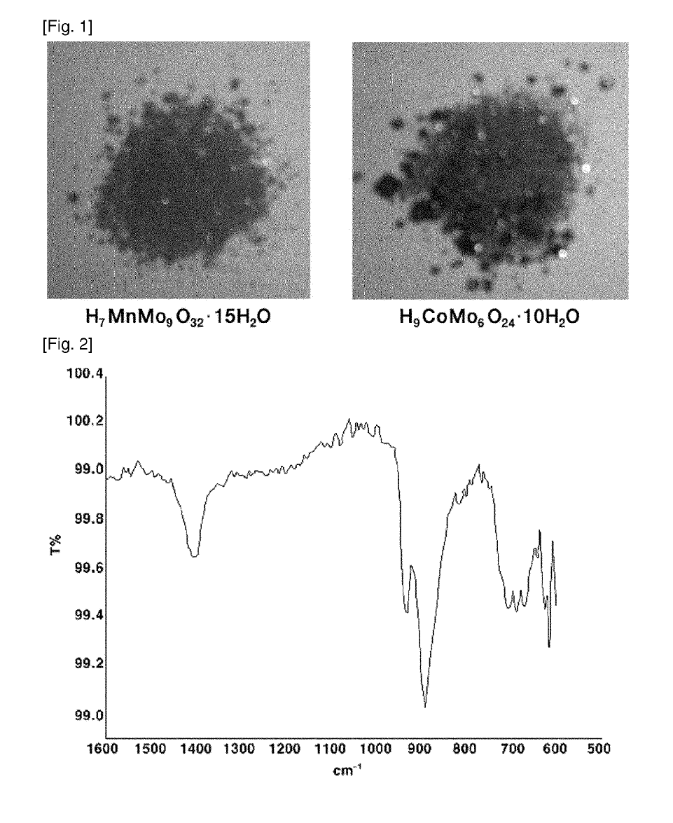

FIG. 1 illustrates the crystal of manganese (III) molybdate that had been obtained from Example 1.

### Production Example 2

### Synthesizing of Manganese (III) Molybdate (H₇MnMo₉O₃₂.15H₂O)

80 mL of distilled water and 30 percent of 14 mL hydrogen peroxide are placed in the beaker to be stirred wherein four grams of monohydrate molybdenum oxide (MoO₃.H₂O) is added in. During this stage, color of the solution was greenish yellow. Four grams of sulfurized manganese hydrate (MnSO₄.H₂O) was placed into the solution and was heated for 30 minutes at 70 degree Celsius. After this, color of the solution changed to orange then heated again for 30 minutes at 90 degree Celsius wherein color of the solution changed to darker shade of orange. Concentrated solution was filtered with filter paper while still hot wherein it was placed in room temperature all night for crystallization after small amount of yellowish deposit had been removed. 2.9 grams of solid, orange colored crystal with 70 percent yield rate was obtained.

### Production Example 3

### Synthesizing of Manganese (III) Molybdate (H₇MnMo₉O₃₂.15H₂O)

80 mL of distilled water and 30 percent of 14 mL hydrogen peroxide are placed in the beaker to be stirred wherein four grams of monohydrate molybdenum oxide (MoO₃.H₂O) is added in. During this stage, color of the solution was greenish yellow. Four grams of manganese acetate dihydrate (Mn(CH₃COO)₃.2H₂O) was placed into the solution and was heated for 30 minutes at 70 degree Celsius. After this, color of the solution changed to orange then heated again for 30 minutes at 90 degree Celsius wherein color of the solution changed to darker shade of orange. Concentrated solution was filtered with filter paper while still hot wherein it was placed in room temperature all night for crystallization after small amount of yellowish deposit had been removed. 2.6 grams of solid, orange colored crystal with 63 percent yield rate was obtained.

### Production Example 4

### Synthesizing of Cobalt (III) Molybdate (H₉CoMo₆O₂₄.10H₂O)

80 mL of distilled water and 30 percent of 15 mL hydrogen peroxide are placed in the beaker to be stirred wherein six grams of monohydrate molybdenum oxide (MoO₃.H₂O) was added in. During this stage, color of the solution was greenish yellow. Six grams of cobalt chloride hexahydrate (CoCl₂.6H₂O) was placed into the solution slowly in the room temperature. After this, color of the solution changed to light burgundy. Temperature was slowly raised to 70 degree Celsius to be heated for 30 minutes. It was heated again for 30 minutes at 90 degree Celsius wherein color of the solution changed to darker shade of burgundy. Concentrated solution was filtered with filter paper while still hot wherein it was placed in room temperature all night for crystallization after small amount of impurity had been removed. 3.8 grams of solid, blue colored crystal with 56 percent yield rate was obtained.

FIG. 1 illustrates the crystal of cobalt (III) molybdate that had been obtained from Example 4.

### Production Example 5

### Synthesizing of Cobalt (III) Molybdate (H₉CoMo₆O₂₄.10H₂O)

80 mL of distilled water and 30 percent of 15 mL hydrogen peroxide are placed in the beaker to be stirred wherein six grams of monohydrate molybdenum oxide (MoO₃.H₂O) was added in. During this stage, color of the solution was greenish yellow. Six grams of sulfurized heptahydrate (CoSO₄.7H₂O) was placed into the solution slowly in the room temperature. After this, color of the solution changed to red brown. Temperature was slowly raised to 70 degree Celsius to be heated for 30 minutes. It was heated again for 30 minutes at 90 degree Celsius wherein color of the solution changed to darker shade of burgundy. Concentrated solution was filtered with filter paper while still hot wherein it was placed in room temperature all night for crystallization after small amount of impurity had been removed. 4.8 grams of solid, blue colored crystal with 70 percent yield rate was obtained.

### Production Example 6

### Synthesizing of Cobalt (III) Molybdate (H₉CoMo₆O₂₄.10H₂O)

80 mL of distilled water and 30 percent of 15 mL hydrogen peroxide are placed in the beaker to be stirred wherein six grams of monohydrate molybdenum oxide (MoO₃.H₂O) was added in. During this stage, color of the solution was greenish yellow. Six grams of cobalt acetate tetrahydrate (Co(CH₃COO)₂.4H₂O) was placed into the solution slowly in the room temperature. After this, color of the solution changed to red brown. Temperature was slowly raised to 70 degree Celsius to be heated for 30 minutes. It was heated again for 30 minutes at 90 degree Celsius wherein color of the solution changed to darker shade of burgundy. Concentrated solution was filtered with filter paper while still hot wherein it was placed in room temperature all night for crystallization after small amount of impurity had been removed. 4.2 grams of solid, blue colored crystal with 61 percent yield rate was obtained.

In order to identify the structure of metal polyoxide, flexible or bent vibrational energy of functional group was checked through Fourier transform ultraviolet ray spectrometry and each compound was checked through ultraviolet visible light (UV-Vis). Moreover, inductive coupling plasma spectrometry was used to check the component of metal atom in metal polyoxides wherein molecular formula was obtained by clearly identifying the solid crystal structure of metal polyoxides through single crystal x-ray crystallography.

Results of the measurement are as follows.

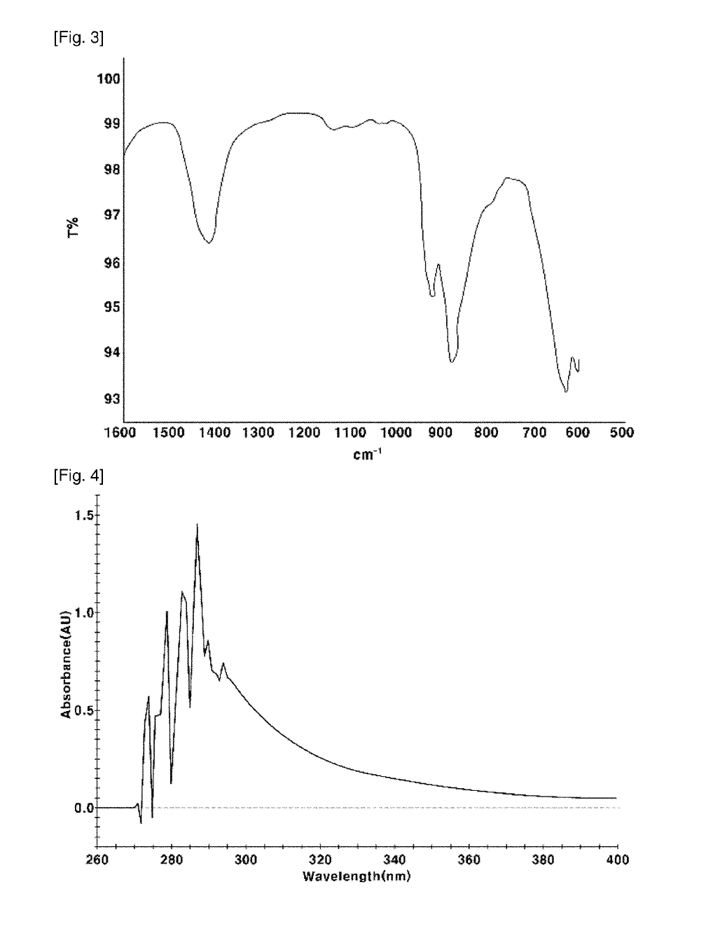

1) Fourier transformation infrared ray spectrometry (FT-IR): Refer to FIG. 2 and FIG. 3

Manganese (III) molybdate (H₇MnMo₉O₃₂.15H₂O): Mo—O—Mo 891 cm⁻¹, Mn═O 932 cm⁻¹

Cobalt (III) molybdate (H₉CoMo₆O₂₄.10H₂O): Mo—O—Mo 883 cm⁻¹, Mn═O 921 cm⁻¹

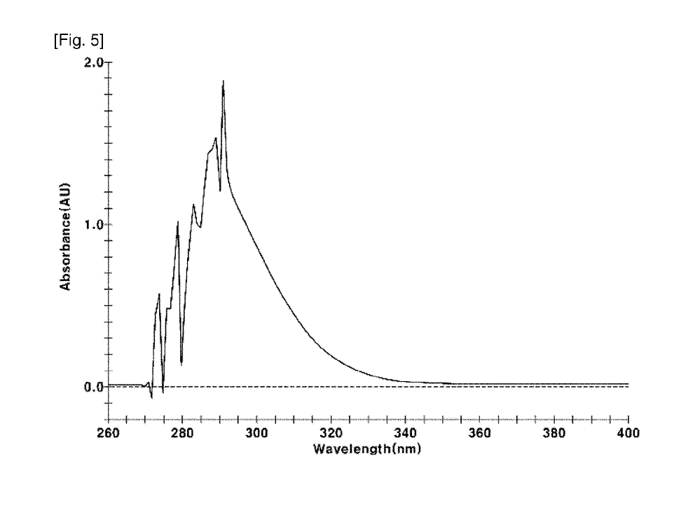

2) Ultraviolet visible light (UV-Vis) spectrometry: Refer to FIG. 4 and FIG. 5

3) Inductive coupling plasma spectrometry (ICP spectrometry)

Manganese (III) molybdate (H₇MnMo₉O₃₂.15H₂O): 5.11% Mn, 53.05% Mo (calcd Mn 3.22%, Mo 50.56%)

Cobalt (III) molybdate (H₉CoMo₆O₂₄.10H₂O): 5.12% Co, 48.61% Mo (calcd Co 4.88%, Mo 47.66%)

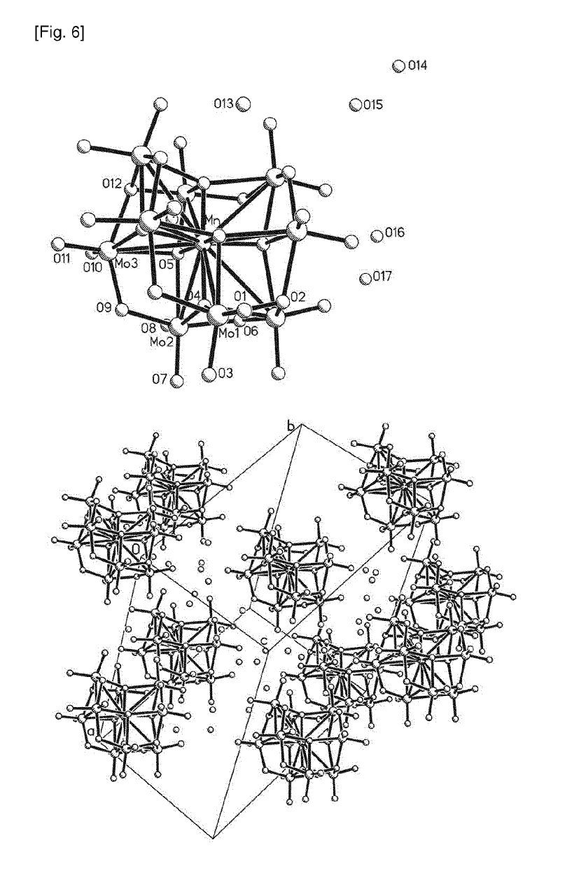

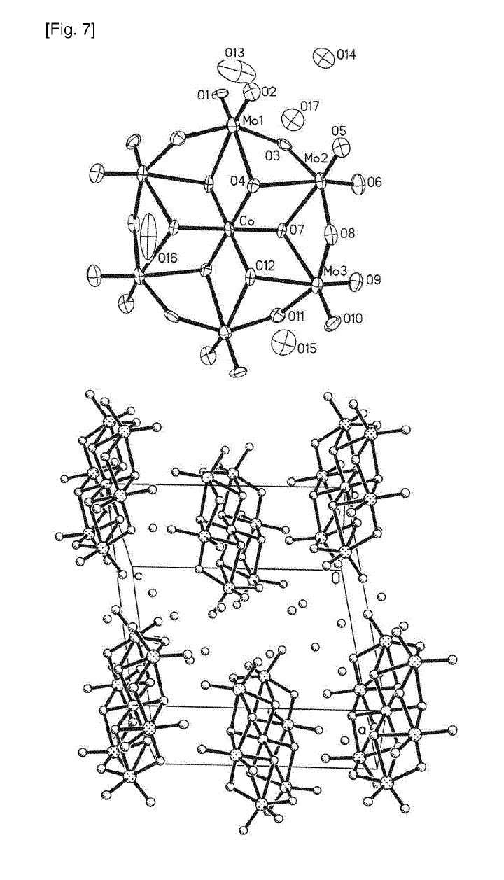

4) Single crystal X-ray crystallography: Refer to FIG. 6 and FIG. 7

Manganese (III) molybdate (H₇MnMo₉O₃₂.15H₂O): CSD-423179,

Cobalt (III) molybdate (H₉CoMo₆O₂₄.10H₂O): CSD-423180.

### REFERENCE EXAMPLE

### Method of Anionization or Cationization of Fiber of Textile

### Reference Example 1

### Producing of Cationized Cellulose Fiber

### 1) Producing of Anionic Cellulose Fiber

Cellulose was immersed into chloride acetate solution in order to produce electron capture ionized fiber. Cellulose and chloride acetate solution were made to react with each other in the weight ratio of 50:1 to produce electron capture ionized fiber.

CICH₂COO+Cellulose-OH→Cellulose-O—CH₂COO

### 2) Producing of Cationized Cellulose Fiber

Cellulose fiber produced in reference example 1 had been cationized by 2-chloroethyldiethylamine hydrogen chloride (DEAEC1.HCl) and the process is as follows.

Anionic cellulose fiber is completely immersed in 20% DEAEC1.HCl solution for 30 minutes and dried. Then it is completely immersed in 20% DEAEC1.HCl solution for 30 minutes and dried again. Afterwards, was immersed in 8% sodium hydroxide solution for 10 minutes at 95 degree Celsius. During this process, DEAEC1.HCl is neutralized and becomes DEAEC1, then afterwards DEAE+ positive ion wherein the alcohol of the cellulose loses hydrogen and becomes ionized. It was dried all night in room temperature after DEAE+ cellulose with alkalinity amine was washed with water. Through this process, cationized cellulose fiber with multiple number of nitrogen was produced.

### Reference Example 2

### Producing of Cationized Cellulose Textile

### 1) Producing of Anionic Cellulose Textile

Cellulose textile was completely immersed in the 20% of hydrated sodium for five minutes and dried for 15 minutes at 45 degree Celsius. Then, it was immersed in ammonium chloroacetate and heated at 85 degree Celsius for five minutes and washed with water, acidified with acetate solution, washed with water again and dried in room temperature with air.

Anionization process for cellulose textile is shown as follows.

Cellulose-OH +NaOH→Cellulose-O—Na

Cellulose-O—Na+CICH₂COONH₄→Cellulose-O—CH₂COONH₄

Cellulose-O—CH₂COONH₄+CH₃COOH→Cellulose-O—CH₂COO⁻

### 2) Producing of Cationized Cellulose Textile

3-chloro-2-hydroxypropyl trimethyl ammonium chloride (CHTAC): Sodium hydroxide was melted in water with 1:2.2˜2.5 mole ratio and the best mole ratio of 1: 2.5. CHTAC-NaOH solution was diluted in water to produce 20% concentrated solution and ice was used in order to prevent CHTAC from disintegrating as the temperature increases. Afterwards, anionic cellulose textile produced from 1) of reference example 2 was completely immersed in CHTAC-NaOH solution to be left alone for 10 minutes wherein it was dried for 15 minutes in 40 degree Celsius and dried again for 15 minutes in 120 degree Celsius.

It was washed with water, neutralized with acetic acid and dried in the air.

Cationization process of anionic cellulose fiber is shown as follows.

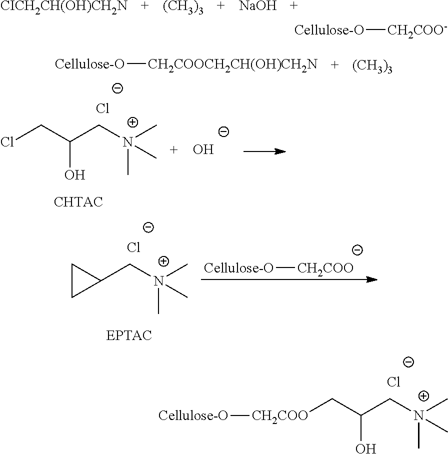

Fourth ammonium placed in cellulose textile through cationization has a very high positive ion wherein it can form a stable ion bonding through anionic and static reaction like metal polyoxide.

### Reference Example 3

### Producing of Cationized Cotton Textile Through Exhaustion Method

Exhaustion method that requires high temperature was used for cationization process of the natural fiber. Cotton textile is immersed in 80 g/L of CHTAC solution set to pH 13 with five percent sodium hydroxide wherein the temperature is slowly increased to 70 degree Celsius and made to react for one hour. The weight ratio of the textile and solution at this stage was 1:20. The textile was washed with cold water several times after it was taken out of the solution and acidified in 1 percent of acetate solution. The textile was then washed again with cold water to be air-dried in room temperature.

### Reference Example 4

### Producing of Cationized Cotton Textile Through Cold Pad-Batch Method

Cold pad-batch method was used for cationization process of the natural fiber. Cotton textile was immersed in 120 to 130 g/L of CHTAC solution along with 50 g/L of sodium hydroxide was prepared wherein the cotton textile was immersed in the solution for 15 hours in room temperature. The weight ratio of the textile and solution at this stage was 1:20. The textile was washed with cold water several times after it was taken out of the solution and neutralized in 2 g/L acetate solution. The textile was then washed once again with water to be air-dried in room temperature.

### EXAMPLE

### Production of Functional Fiber or Textile

### Example 1

### Producing of Functional Cotton Textile Fused with Potassium Phosphorus Molybdenum Vanadate and Copper

Stage 1: Cationization Stage

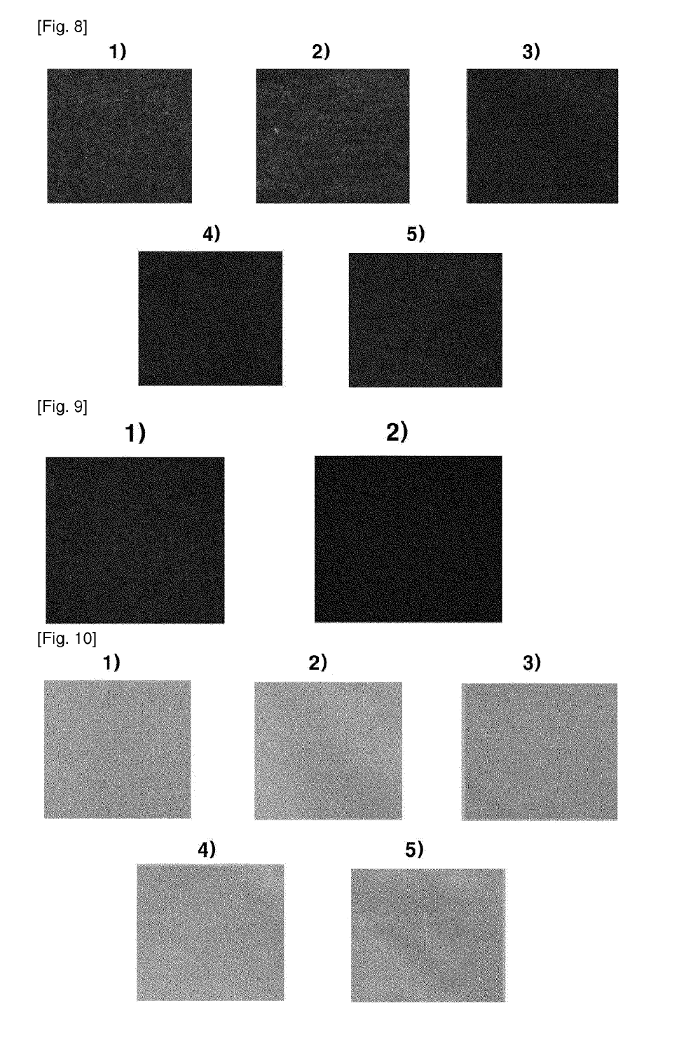

40 grams of cotton textile was prepared to manufacture functional textile wherein the picture of the cotton textile is shown in 1) of FIG. 8. 40 grams of sodium hydroxide, 96 grams of 3-chloro-2-hydroxypropyl trimethyl ammonium chloride (CHTAC; Product name CR2000, Dow Company) and 0.1 gram of sodium lauryl sulfate to be used for anionic surface active agent were blend together to prepare a solution.

Cotton textile is immersed in 0.8 liter of compound solution that had been prepared as above. After 15 hours, cationized textile was washed with water wherein it was washed with 4 percent of acetate solution to be washed again with water to be air-dried in room temperature. Picture of the cotton textile that went through the cationization stage as mentioned above can be seen in 2) of FIG. 8.

Stage 2: Stage Where Metal Polyoxides is Added

2.5 gram of potassium phosphate molybdenum vanadate as metal polyoxide is melted into 0.5 liter of water wherein cationized cotton textile from stage 1 is immersed into it and stirred for 30 minutes. Then the textile is pulled out of the solution and washed with water to eliminate excess metal polyoxide. Cotton textile produced after the stage where metal polyoxides is added can be seen in 3) of FIG. 8.

Stage 3: Stage Where Metal Salt is Added

Cotton textile treated with metal polyoxides produced in stage 2 was immersed in 1 liter of five percent copper chloride (II) solution for 30 minutes. Then the textile is pulled out of the solution and washed with water to eliminate excess metal salt and air-dried in room temperature. Cotton textile produced after the stage where copper is added can be seen in 4) of FIG. 8.

Stage 4: Reduction Stage

Cotton textile from stage 3 is placed in one liter of water and stirred. Ten percent ascorbic acid solution is added as the reducing agent and stirred for 30 minutes. Then the cotton textile is pulled out of the solution, washed with water and air-dried in room temperature. Cotton textile produced after the reduction stage can be seen in 5) of FIG. 8.

### Example 2

### Producing of Functional Cotton Textile Fused with Potassium Phosphorus Molybdenum Vanadate and Silver

Stage 1: Cationization Stage

Cationization process is carried out by the method of stage 1 in example 1 as it had been previously mentioned.

Stage 2: Stage Where Metal Polyoxides is Added

Metal polyoxides of potassium phosphorus molybdenum vanadate is added by stage 2 in example 1 as it had been previously mentioned.

Stage 3: Stage Where Metal Salt is Added

Cotton textile treated with metal polyoxides was immersed in 1 liter of five percent silver chloride (I) solution for 30 minutes. Then the textile is pulled out of the solution and washed with water to eliminate excess metal salt and air-dried in room temperature. Cotton textile produced after the stage where silver is added can be seen in 1) of FIG. 9.

Stage 4: Reduction Stage

Cotton textile from stage 3 is placed in one liter of water and stirred. Ten percent ascorbic acid solution is added as the reducing agent and stirred for 30 minutes. Then the cotton textile is pulled out of the solution, washed with water and air-dried in room temperature. Cotton textile produced after the reduction stage can be seen in 2) of FIG. 9, number 2.

### Example 3

### Producing of Functional Cellulose Textile Fused with Potassium Phosphorus Molybdenum Vanadate and Copper

Stage 1: Cationization Stage

40 grams of cellulose fiber was prepared to manufacture functional textile wherein the picture of the prepared cellulose textile is shown in 1) of FIG. 10. Then, for cationization of the textile, 40 grams of sodium hydroxide, 96 grams of 3-chloro-2-hydroxypropyl trimethyl ammonium chloride (CHTAC; Product name CR2000, Dow Company) and 0.1 gram of sodium lauryl sulfate to be used for anionic surface active agent were blend together to prepare a solution. The prepared cellulose textile is immersed in 0.8 liter of compound solution that had been prepared as above. After 15 hours, cationized textile was washed with water wherein it was washed with 4 percent of acetate solution to be washed again with water to be air-dried in room temperature. Picture of the cellulose textile that went through the cationization stage as mentioned above can be seen in 2) of FIG. 10.

Stage 2: Stage Where Metal Polyoxides is Added

2.5 gram of potassium phosphate molybdenum vanadate as metal polyoxide is melted into 0.5 liter of water wherein cationized cotton textile from stage 1 is immersed into it and stirred for 30 minutes. Then the textile is pulled out of the solution and washed with water to eliminate excess metal polyoxide. Cellulose textile produced after the stage where metal polyoxides is added can be seen in 3) of FIG. 10.

Stage 3: Stage Where Metal Salt is Added

Cotton textile treated with metal polyoxides produced in stage 2 was immersed in 1 liter of five percent copper chloride (II) solution for 30 minutes. Then the textile is pulled out of the solution and washed with water to eliminate excess metal salt and air-dried in room temperature. Cellulose textile produced after the stage where copper is added can be seen in 4) of FIG. 10.

Stage 4: Reduction Stage

Cellulose textile from stage 3 is placed in one liter of water and stirred. Ten percent ascorbic acid solution is added as the reducing agent and stirred for 30 minutes. Then the cellulose textile is pulled out of the solution, washed with water and air-dried in room temperature. Cellulose textile produced after the reduction stage can be seen in FIG. 10, number 5.

### Example 4

### Producing of Functional Cellulose Textile Fused with Ammonium Molybdate and Palladium

Stage 1: Cationization Stage

Cationization process is carried out by the method of stage 1 in example 3 as it had been previously mentioned.

Stage 2: Stage Where Metal Polyoxides is Added

Metal polyoxide of ammonium molybdate is added by stage 2 in example 3 as it had been previously mentioned.

Stage 3: Stage Where Metal Salt is Added

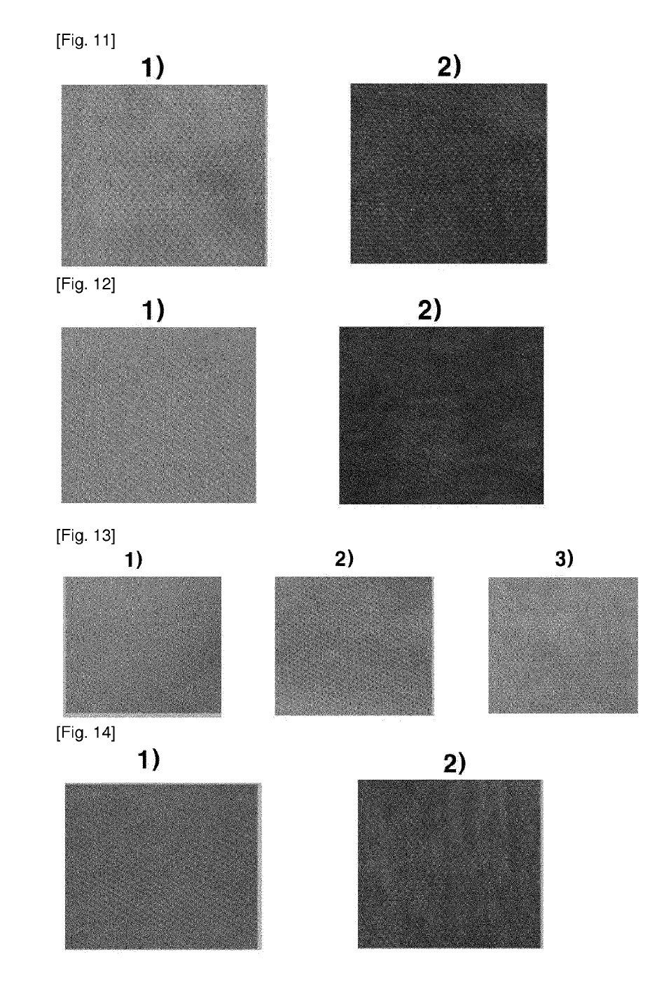

Cellulose textile treated with metal polyoxides in the stage 2 was immersed in 1 liter of five percent palladium chloride solution for 30 minutes. Then the textile is pulled out of the solution and washed with water to eliminate excess metal salt and air-dried in room temperature. Cellulose textile produced after the stage where palladium was added can be seen in 1) of FIG. 11.

Stage 4: Reduction Stage

Cellulose textile from stage 3 is placed in one liter of water and stirred. Ten percent ascorbic acid solution is added as the reducing agent and stirred for 30 minutes. Then the cellulose textile is pulled out of the solution, washed with water and air-dried in room temperature. Cellulose textile produced after the reduction stage can be seen in 2) of FIG. 11.

### Example 5

### Producing of Functional Cellulose Textile Fused with Ammonium Molybdate and Silver

Stage 1: Cationization Stage

Cationization process is carried out by the method of stage 1 in example 3 as it had been previously mentioned.

Stage 2: Stage Where Metal Polyoxides is Added

Metal polyoxides of ammonium molybdate is added by stage 2 in example 3 as it had been previously mentioned.

Stage 3: Stage Where Metal Salt is Added

Cellulose textile treated with metal polyoxides in the stage 2 was immersed in 1 liter of five percent silver chloride (I) solution for 30 minutes. Then the textile is pulled out of the solution and washed with water to eliminate excess metal salt and air-dried in room temperature. Cellulose fiber produced after the stage where silver is added can be seen in 1) of FIG. 12.

Stage 4: Reduction Stage

Cellulose textile from stage 3 is placed in one liter of water and stirred. Ten percent ascorbic acid solution is added as the reducing agent and stirred for 30 minutes. Then the cellulose textile is pulled out of the solution, washed with water and air-dried in room temperature. Cellulose textile produced after the reduction stage can be seen in 2) of FIG. 12.

### Example 6

### Producing of Functional Cotton Textile Fused with Potassium Phosphorus Molybdenum Vanadate and Copper

Stage 1: Cationization Stage

Cationization process is carried out by the method of stage 1 in example 3 as it had been previously mentioned.

Stage 2: Stage Where Metal Polyoxides is Added

Metal polyoxides of potassium phosphorus molybdenum vanadate is added by stage 2 in example 3 as it had been previously mentioned. Cotton textile produced after the stage where metal polyoxides was added can be seen in 1) of FIG. 13.

Stage 3: Stage Where Metal Salt is Added

Cellulose textile treated with metal polyoxides prepared as above was immersed in 1 liter of five percent copper chloride (II) solution for 30 minutes. Then the textile is pulled out of the solution and washed with water to eliminate excess metal salt and air-dried in room temperature. Cotton textile produced after the stage where copper was added can be seen in 2) of FIG. 13.

Stage 4: Reduction Stage

Cotton textile from stage 3 is placed in one liter of water and stirred. Ten percent ascorbic acid solution is added as the reducing agent and stirred for 30 minutes. Then the cellulose textile is pulled out of the solution, washed with water and air-dried in room temperature. Cotton textile produced after the reduction stage can be seen in 3) of FIG. 13.

### Example 7

### Producing of Functional Cellulose Textile with Potassium Phosphorus Molybdenum Vanadate and Silver

Stage 1: Cationization Stage

Cationization process is carried out by the method of stage 1 in example 3 as it had been previously mentioned.

Stage 2: Stage Where Metal Polyoxides is Added

Metal polyoxides of potassium phosphorus molybdenum vanadate is added by stage 2 in example 3 as it had been previously mentioned.

Stage 3: Stage Where Metal Salt is Added

Cellulose textile treated with metal polyoxides prepared as above was immersed in 1 liter of five percent silver chloride (I) solution for 30 minutes. Then the textile is pulled out of the solution and washed with water to eliminate excess metal salt and air-dried in room temperature. Cellulose textile produced after the stage where silver is added can be seen in FIG. 14, number 1.

Stage 4: Reduction Stage

Cellulose textile from stage 3 is placed in one liter of water and stirred. Ten percent ascorbic acid solution is added as the reducing agent and stirred for 30 minutes. Then the cellulose textile is pulled out of the solution, washed with water and air-dried in room temperature. Cellulose textile produced after the reduction stage can be seen in 2) of FIG. 14.

### Example 8

### Producing of Functional Cellulose Textile Fused with Silicon Molybdate and Copper

Stage 1: Cationization Stage

Cationization process is carried out by the method of stage 1 in example 3 as it had been previously mentioned.

Stage 2: Stage Where Metal Polyoxides is Added

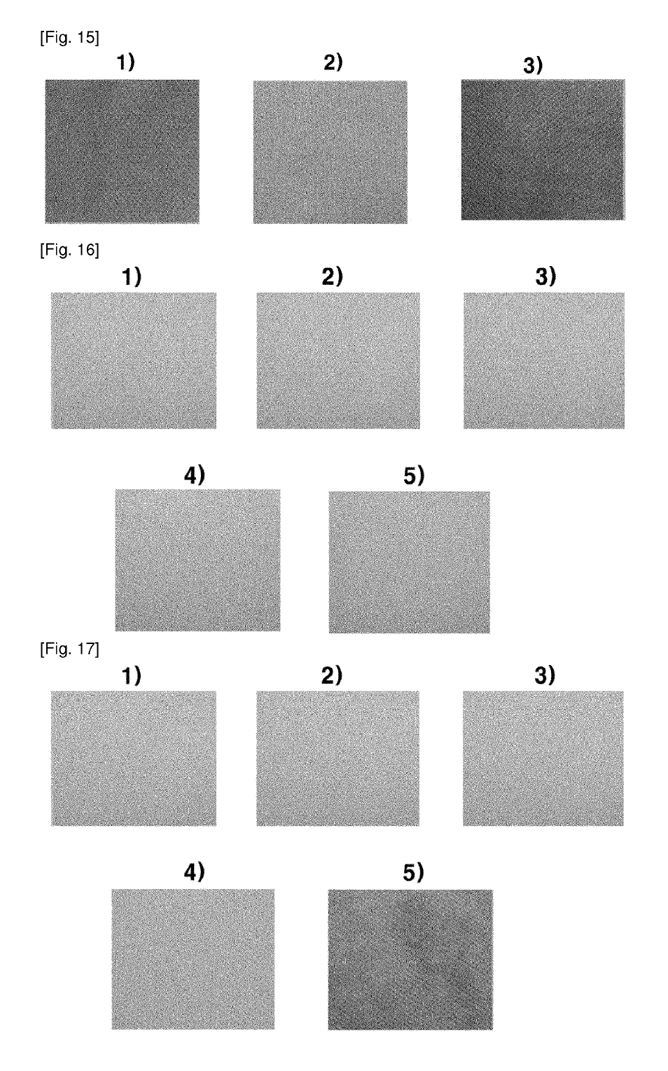

Metal polyoxides of silicon molybdate is added by stage 2 in example 3 as it had been previously mentioned. Cellulose textile produced after the stage where metal polyoxides is added can be seen in 1) of FIG. 15.

Stage 3: Stage Where Metal Salt is Added

Cellulose textile treated with metal polyoxides in the stage 2 was immersed in 1 liter of five percent copper chloride (II) solution for 30 minutes. Then the textile is pulled out of the solution and washed with water to eliminate excess metal salt and air-dried in room temperature. Cellulose textile produced after the stage where copper is added can be seen in 2) of FIG. 15.

Stage 4: Reduction Stage

Cellulose textile from stage 3 is placed in one liter of water and stirred. Ten percent ascorbic acid solution is added as the reducing agent and stirred for 30 minutes. Then the cellulose textile is pulled out of the solution, washed with water and air-dried in room temperature. Cellulose textile produced after the reduction stage can be seen in 3) of FIG. 15.

### Example 9

### Producing Of Functional Cotton Textile Fused with Manganese (iii) Molybdate and Copper

Stage 1: Cationization Stage

40 grams of cotton textile was prepared to manufacture functional textile wherein the picture of the cotton textile is shown in 1) of FIG. 16. For cationization of the textile, 40 grams of sodium hydroxide, 96 grams of 3-chloro-2-hydroxypropyl trimethyl ammonium chloride (CHTAC; Product name CR2000, Dow Company) and 0.1 gram of sodium lauryl sulfate to be used for anionic surface active agent were blend together to prepare a solution. Cotton textile is immersed in 0.8 liter of compound solution that had been prepared as above. After 15 hours, cationized cotton textile was washed with water wherein it was washed with 4 percent of acetate solution to be washed again with water to be air-dried in room temperature. Picture of the cotton textile that went through the cationization stage as mentioned above can be seen in 2) of FIG. 16.

Stage 2: Stage Where Metal Polyoxides is Added

Cationized cotton textile from stage 1 was immersed and stirred for 30 minutes in a solution wherein 2.5 gram crystal of manganese (III) molybdate (H7MnMo9O32.15H2O) is melted into 0.5 liter of water. Then the textile is pulled out of the solution and washed with water to eliminate excess manganese (III) molybdate. Cotton textile produced after the stage where metal polyoxides is added can be seen in 3) of FIG. 16.

Stage 3: Stage Where Metal Salt is Added

Cotton textile treated with manganese (III) molybdate in 1) of stage 2 was immersed in 1 liter of five percent copper chloride (II) solution for 30 minutes. Then the textile is pulled out of the solution and washed with water to eliminate excess metal salt and air-dried in room temperature. Cotton textile produced after the stage where copper was added can be seen in 4) of FIG. 16.

Stage 4: Reduction Stage

Cotton textile from stage 3 is placed in one liter of water and stirred. Ten percent ascorbic acid solution is added as the reducing agent and stirred for 30 minutes. Then the cotton textile is pulled out of the solution, washed with water and air-dried in room temperature. Cotton textile produced after the reduction stage can be seen in 5) of FIG. 16.

### Example 10

### Producing of Functional Cotton Textile Fused with Cobalt (III) Molybdate and Silver

Stage 1: Cationization Stage

40 grams of cotton textile was prepared to manufacture functional textile wherein the picture of the prepare cotton textile is shown on 1) of FIG. 17. For cationization of the textile, 40 grams of sodium hydroxide, 96 grams of 3-chloro-2-hydroxypropyl trimethyl ammonium chloride (CHTAC; Product name CR2000, Dow Company) and 0.1 gram of sodium lauryl sulfate to be used for anionic surface active agent were blend together to prepare a solution. Cotton textile is immersed in 0.8 liter of compound solution that had been prepared as above. After 15 hours, cationized cotton textile was washed with water wherein it was washed with 4 percent of acetate solution to be washed again with water to be air-dried in room temperature. Picture of the cotton textile that went through the cationization stage as mentioned above can be seen in 2) of FIG. 17.

Stage 2: Stage Where Metal Polyoxides is Added

Cotton textile treated with manganese (III) molybdate is immersed and stirred for 30 minutes in a solution wherein 2.5 gram crystal of Cobalt (III) Molybdate (H₉CoMo₆O₂₄.10H₂O) is melted into 0.5 liter of water. Then the textile is pulled out of the solution and washed with water to eliminate excess cobalt (III) molybdate. Cotton textile produced after the stage where metal polyoxides is added can be seen in 3) of FIG. 17.

Stage 3: Stage Where Metal Salt is Added

Cotton textile treated with Cobalt (III) Molybdate in stage 2 was immersed in 1 liter of five percent silver chloride (I) solution for 30 minutes. Then the textile is pulled out of the solution and washed with water to eliminate excess metal salt and air-dried in room temperature. Cotton textile produced after the stage where silver was added can be seen in FIG. 17, number 4.

Stage 4: Reduction Stage

Cotton textile from stage 3 is placed in one liter of water and stirred. Ten percent ascorbic acid solution is added as the reducing agent and stirred for 30 minutes. Then the cotton textile is pulled out of the solution, washed with water and air-dried in room temperature. Cotton textile produced after the reduction stage can be seen in 5) of FIG. 17.

### TEST EXAMPLE

### Test Example 1

### Surface of the Functional Fiber or Textile Fused with Metal Polyoxide

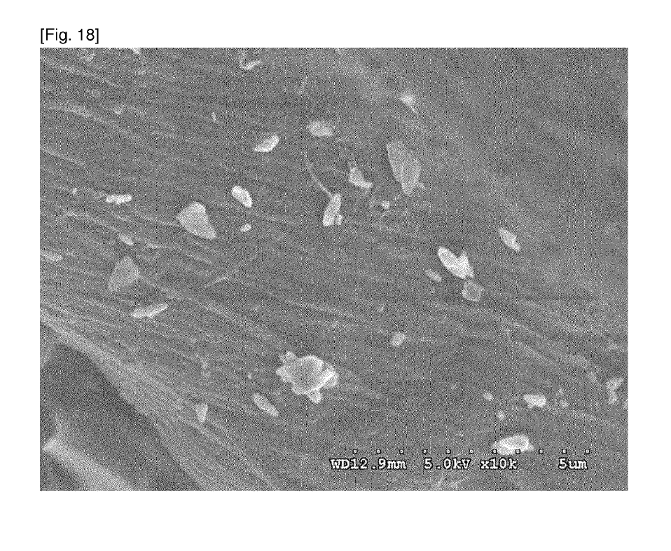

Scanning electronic microscope was used in order to verify the fusion of metal polyoxide and metal salt into the fiber or textile. FIG. 18 illustrates the picture of functional cotton textile as produced by steps of example 10.

It was verified that metal polyoxide and metal salt was successfully fused with the surface of fiber or textile according to the picture of scanning electronic microscope.

### Test Example 2

### Antibacterial Effect of Metal Polyoxide

In order to verify the antibacterial effect of functional textile treated with metal polyoxide, antibacterial effectiveness test was administered by Korea Apparel Testing & Research Institute to the cotton textile fused with manganese (III) molybdate and copper as seen on example 9 as per request.

This test was in accordance with KS K 0693-2006 and Staphylococcus aureus 6538 and Klebsiella pneumonia ATCC 4352 were used as Escherichia coli.

Test group and control group were cultivated and inoculated with Escherichia coli wherein bacteria cultivated in certain amount of liquid by shake culture was extracted. When the amount of bacteria existing in the liquid was measured, mathematical equation 1 was used in order to figure out the reduction ration of the bacteria from the test group with antibacterial function. The result is shown in the Table 1 as below.

$$[ Mathematical formula 1 ]$$

$$Bacteria reducing rate ( \% ) = \frac{\begin{matrix}( \begin{matrix}Number of bacteria after 18 hours \\ of cultivation from control group\end{matrix} ) - \\ ( \begin{matrix}Number of bacteria after 18 hours \\ of cultivation from test group\end{matrix} )\end{matrix}}{( \begin{matrix}Number of bacteria after 18 hours \\ of cultivation from control group\end{matrix} )} \times 100$$

TABLE 1

| | Staphylococcus aureus | | | Klebsiella pneumonia | | |
|---|---|---|---|---|---|---|
| | Initial number | 18 hours | | Initial number | 18 hours | |
| | of bacteria | later | Bacteria | of bacteria | later | Bacteria |
| | (number of | (number of | reduction | (number of | (number of | reduction |
| Classification | bacteria/mL) | bacteria/mL) | rate | bacteria/mL) | bacteria/mL) | rate |
| Control group | 2.1 × 10⁴ | 4.1 × 10⁶ | — | 2.1 × 10⁴ | 6.3 × 10⁶ | — |
| Example 1 | 2.1 × 10⁴ | 7.5 × 10 | 99.9 | 2.1 × 10⁴ | 2.5 × 10 | 99.9 |
| Example 2 | 2.1 × 10⁴ | 8.1 × 10² | 99.9 | 2.1 × 10⁴ | 4.1 × 10² | 99.9 |
| Example 3 | 2.1 × 10⁴ | <10 | 99.9 | 2.1 × 10⁴ | <10 | 99.9 |
| Example 4 | 2.1 × 10⁴ | <10 | 99.9 | 2.1 × 10⁴ | <10 | 99.9 |
| Example 5 | 2.1 × 10⁴ | <10 | 99.9 | 2.1 × 10⁴ | <10 | 99.9 |
| Example 6 | 2.1 × 10⁴ | <10 | 99.9 | 2.1 × 10⁴ | <10 | 99.9 |
| Example 7 | 2.1 × 10⁴ | <10 | 99.9 | 2.1 × 10⁴ | <10 | 99.9 |
| Example 8 | 2.1 × 10⁴ | <10 | 99.9 | 2.1 × 10⁴ | <10 | 99.9 |
| Example 9 | 2.1 × 10⁴ | <10 | 99.9 | 2.1 × 10⁴ | <10 | 99.9 |
| Example 10 | 2.1 × 10⁴ | <10 | 99.9 | 2.1 × 10⁴ | <10 | 99.9 |

### Test Example 3

### House Tick Extermination Effect of Functional Fiber or Textile

In order to test the tick extermination effect of functional fiber or textile that had been treated with metal polyoxide, tick extermination test was administered through the test tube.

Test tube was placed sideways wherein tick with regular paper was placed on one end, natural cotton in the middle. Test piece, which is the functional textile of the present invention, and bait to lure the tick was placed on the other end to be sealed. After 48 hours have passed in the sealed environment, number of ticks at the side of the test piece was counted.

For the control group, natural textile that did not undergo any treatment was used and dust mites were used for ticks. Result of the test is as shown below on table 2.

TABLE 2

| | Initial number of | Number of ticks | Avoidance rate |
|---|---|---|---|
| Classification | ticks | after 48 hours | (%) |
| Control group | 5.8 × 10⁴ | 6.4 × 10³ | — |
| Example 1 | 5.6 × 10⁴ | <10 | 99.9 |
| Example 2 | 5.4 × 10⁴ | <10 | 99.9 |
| Example 3 | 5.3 × 10⁴ | <10 | 99.9 |
| Example 4 | 5.6 × 10⁴ | <10 | 99.9 |
| Example 5 | 5.6 × 10⁴ | <10 | 99.9 |
| Example 6 | 5.6 × 10⁴ | <10 | 99.9 |
| Example 7 | 5.6 × 10⁴ | <10 | 99.9 |
| Example 8 | 5.6 × 10⁴ | <10 | 99.9 |
| Example 9 | 5.6 × 10⁴ | 0 | 99.9 |
| Example 10 | 5.4 × 10⁴ | 0 | 99.9 |

As it can be seen by the result of Table 2, tick avoidance rate of functional fiber or textile according to the present invention is excellent with the avoidance rate of 99.9% Therefore, it can be concluded that functional fiber or textile according to the present invention suppresses the dust mites from spreading which cause various diseases such as atopy, allergies, asthma, rhinitis among others.

### Test Example 4

### Deodorizing Effect of Functional Fiber or Textile

In order to verify the deodorizing effect of functional textile treated with metal polyoxide of the present invention, deodorizing effectiveness test was administered by Korea Apparel Testing & Research Institute as per request.

This test was administered with ammonia gas in accordance with gas detection law to test for deodorizing effect wherein the initial concentration of ammonia was 500 ug/mL. Deodorizing rate was calculated after 30 minute, 60 minute, 90 minute and 120 minute to calculate the deodorizing rate according to the mathematical formula 2 as seen below. Result of the test is shown in table 3 as below.

$$[ Mathematical formula 2 ]$$

$$Deodorizing Rate ( \% ) = \frac{\begin{matrix}Gas concentration of control group - \\ Gas concentration of test group\end{matrix}}{Gas concentration of control group} \times 100$$

TABLE 3

| | Deodorizing rate (%) | | | |
|---|---|---|---|---|
| Classification | 30 minute | 60 minute | 90 minute | 120 minute |
| Example 1 | 80 | 83 | 87 | 90 |
| Example 2 | 75 | 77 | 78 | 79 |
| Example 3 | 77 | 79 | 83 | 88 |
| Example 4 | 82 | 85 | 87 | 90 |
| Example 5 | 80 | 87 | 89 | 93 |
| Example 6 | 76 | 79 | 81 | 83 |
| Example 7 | 79 | 83 | 87 | 94 |
| Example 8 | 99 | 99.3 | 99.4 | 99.4 |
| Example 9 | 99 | 99.3 | 99.6 | 99.7 |
| Example 10 | 99 | 99.3 | 99.6 | 99.7 |

### Test Example 5

### Surface Electrical Resistance Effect of Functional Fiber or Textile

In order to verify the electrical resistance effect of functional fiber or textile treated with metal polyoxide of the present invention, electrical effectiveness test was administered by FITI Research Center as per request. Test piece requested to FITI Research Center was functional cellulose textile fused with ammonium molybdate and copper as per example 3 and cellulose textile before ammonium molybdate and copper was applied as the control group.

This test was carried out in accordance with KS K 0170. In the environment where temperature of 20±2° C. and humidity of 40±2% RH was maintained, 60 seconds of electricity with 100 Volt was provided. Surface resistance value that had been measured in this manner is shown on Table 4.

TABLE 4

| Classification | Surface resistance value^{(Ω)} |
|---|---|
| Example 3 | 7.2 × 10¹¹ |
| Control group | 3.4 × 10¹⁰ |

According to Table 4, functional fiber or textile according to the present invention has the surface electrical resistance value of 7.2×10¹¹ which is 20 times more than surface resistance value of the control group which is 3.4×10¹⁰. As the surface resistance value had increased 20 times, flow of electric current has lessened by 20 times which provides the effect of blocking the electromagnetic wave 20 times more.

1. Metal polyoxide as represented by chemical formula 1 or chemical formula 2 as below.
H₇MnMo₉O₃₂.xH₂O [Chemical Formula 1]
(In chemical formula 1 as seen above, x is the number of water wherein it is a real number from 10 to 20)
H₉CoMo₆O₂₄.yH₂O [Chemical Formula 2]
(In chemical formula 2 as seen above, y is the number of water wherein it is a real number of 5 to 15)

2. Method for producing metal polyoxides represented by chemical formula 1 or chemical formula 2 as follows wherein the method comprises:
stage (i) wherein hydrated molybdenum oxide is added to aqueous solution of hydrogen peroxide to produce aqueous solution of molybdenum;
stage (ii) wherein metal compound solution is produced by adding hydrated manganese or hydrated cobalt to the aqueous solution of molybdenum to be heated afterwards;
stage (iii) wherein the metal compound solution is concentrated; and
stage (iv) wherein the concentrated solution is crystallized to retrieve crystal of metal polyoxides;
H₇MnMo₉O₃₂.xH₂O [Chemical Formula 1]
(In chemical formula 1 as seen above, x is the number of water wherein it is a real number from 10 to 20)
H₉CoMo₆O₂₄.yH₂O [Chemical Formula 2]
(In chemical formula 2 as seen above, y is the number of water wherein it is a real number of 5 to 15)

3. Producing method of metal polyoxide of claim 2 wherein manganese hydrate of the stage (ii) is manganese chloride tetrahydrate (MnCl₂.4H₂O), sulfurized manganese hydrate (MnSO₄.H₂O) or manganese acetate dihydrate (Mn(CH₃COO)₃.2H₂O), wherein the cobalt hydrate is cobalt chloride hexahydrate (CoCl₂.6H₂O), cobalt sulfide heptahydrate (CoSO₄.7H₂O) or cobalt acetate tetrahydrate (Co(CH₃COO)₂.4H₂O).

4. Producing method of metal polyoxide of claim 2 wherein heating temperature in the stage (ii) is within the range of 60 to 80 degree Celsius.

5. Producing method of metal polyoxide of claim 2 wherein concentration in the stage (iii) occurs with the temperature range of 80 to 100 degree Celsius for 30 to 60 minutes.

6. Producing method of functional fiber or textile with metal polyoxide added thereto wherein the method comprises:
stage (a) wherein fiber or textile is cationized; and
stage (b) wherein the cationized fiber or textile is immersed into aqueous solution of metal polyoxides which includes one or more transition metals selected from tungsten, molybdenum, manganese, cobalt, vanadium and chrome to add the metal polyoxides.

7. Producing method of functional fiber or textile wherein the method comprises:
stage (a) wherein fiber or textile is cationized;
stage (b) wherein the cationized fiber or textile is immersed into aqueous solution of metal polyoxides which includes one or more transition metals selected from tungsten, molybdenum, manganese, cobalt, vanadium and chrome to add the metal polyoxides; and
stage (c) wherein the functional fiber or textile with metal polyoxides added thereto is immersed into aqueous solution which includes one or two or more functional metal salt selected from the group of silver, copper, tin, zinc and palladium to add the functional metal.

8. Producing method of functional fiber or textile of claim 6 wherein the fiber or textile used in the stage (a) went through a pretreatment process for anionization.

9. Producing method of functional fiber or textile of claim 6 wherein the fiber used are natural fiber, artificial fiber or fiber blend thereof.

10. Producing method of functional fiber or textile of claim 9 wherein the fiber is one or two or more selected from the group consisting of flax, ramie, paper mulberry, cotton, silk, wool and cashmere.

11. Producing method of functional fiber or textile of claim 6 wherein the cationization in the stage (a) is carried out by using cationic reagent selected from the group consisting of 2-chloroethyldiethylamine hydrogen chloride, 3-chloro-2-hydroxypropyl trimethyl ammonium chloride and the compound thereof.

12. Producing method of functional fiber or textile of claim 6 wherein the cationization is carried out by means of exhaustion method or cold pad-batch method.

13. Producing method of functional fiber or textile of claim 6 wherein the metal polyoxide is selected from the group consisting of oxide of transition metal, oxide of metal in which phosphorous or silicon is additionally included in transition metal, and alkali metal salt or ammonium salt of the oxides.

14. Producing method of functional fiber or textile of claim 13 wherein the metal polyoxides is one or two or more selected from the group consisting of potassium phosphorus molybdenum vanadate, potassium phosphorus tungsten vanadate, phosphorus molybdenum vanadate, sodium phosphorous molybdenum vanadate, silicon molybdate, phosphomolybdate, phosphotungstate, ammonium molybdate, ammonium polyoxomolybdate, manganese molybdate represented by the following chemical formula 1 and cobalt molybdate represented by the following chemical formula 2.
H₇MnMo₉O₃₂.xH₂O [Chemical Formula 1]
(In chemical formula 1 as seen above, x is the number of water wherein it is a real number from 10 to 20)
H₉CoMo₆O₂₄.yH₂O [Chemical Formula 2]
(In chemical formula 2 as seen above, y is the number of water wherein it is a real number of 5 to 15)

15. Functional fiber or textile with metal polyoxide added thereto wherein metal polyoxide comprising one or more transition metal selected from tungsten, molybdenum, manganese, cobalt, vanadium and chrome is included in the fiber or textile through ionic bonding.

16. Functional fiber or textile of claim 15 wherein one or two or more functional metal selected from the group consisting of silver, copper, tin, zinc and palladium is additionally included in the fiber or textile.

17. Functional fiber or textile of claim 15 wherein the metal polyoxides is one or two or more selected from the group consisting of potassium phosphorus molybdenum vanadate, potassium phosphorus tungsten vanadate, phosphorus molybdenum vanadate, sodium phosphorous molybdenum vanadate, silicon molybdate, phosphomolybdate, phosphotungstate, ammonium molybdate, ammonium polyoxomolybdate, manganese molybdate represented by the following chemical formula 1 and cobalt molybdate represented by the following chemical formula 2.
H₇MnMo₉O₃₂.xH₂O [Chemical Formula 1]
(In chemical formula 1 as seen above, x is the number of water wherein it is a real number from 10 to 20)
H₉CoMo₆O₂₄.yH₂O [Chemical Formula 2]
(In chemical formula 2 as seen above, y is the number of water wherein it is a real number of 5 to 15)

18. Paper wherein it is produced with functional fiber or textile according to claim 15.

19. Clothing wherein it is produced with functional fiber or textile according to claim 15.

20. Sanitary aid wherein it is produced with functional fiber or textile according to claim 15.
